(19) United States
(12) Patent Application Publication
(10) Pub. No.: US 2005/0215077 A1
(43) Pub. Date: Sep. 29, 2005

(54) Method for manufacturing a polycrystalline semiconductor film, apparatus thereof, and image display panel

(76) Inventors: Kazuo Takeda, Tokorozawa (JP); Takeshi Sato, Kokubunji (JP); Jun Gotoh, Mobara (JP); Masakazu Saitou, Mobara (JP); Daisuke Mutou, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/028,864

(22) Filed: Jan. 5, 2005

(30) Foreign Application Priority Data
Mar. 24, 2004 (JP) 2004-086641

(51) Int. Cl. H01L 21/26; H01L 21/42

(52) U.S. Cl. 438/795

(57) ABSTRACT

The generation of a projecting intensity distribution in an irradiation laser beam used for forming a polycrystalline semiconductor film is prevented by irradiating the laser beam onto an amorphous semiconductor film to crystallize it while it is being scanned. A dog-ear removing filter for eliminating diffracted light that occurs at boundaries of lenses and acts as a cause of development of dog-ears in the light intensity distribution is disposed in an optical system to cause the light intensity distribution in the irradiation laser beam to be uniform. As a result, by removing the dog ear distributions, the necessity for making the light intensity distribution of the laser beam blur is eliminated, and, consequently, a distribution of high energy efficiency can be maintained and the throughput is improved.

### CLAIM OF PRIORITY

The present application claims priority from Japanese application JP 2004-086641, filed on Mar. 24, 2004, the content of which is hereby incorporated by reference into this application.

### FIELD OF THE INVENTION

The present invention relates in general to an apparatus for manufacturing a polycrystalline semiconductor film that constitutes the active elements of a liquid crystal display device, an organic electronic display device, and other various semiconductor devices, which apparatus is suitable particularly for use in the manufacture of an image display panel.

### BACKGROUND OF THE INVENTION

An active-matrix type liquid crystal display device, the use of a polycrystalline silicon film (hereinafter referred to as a polysilicon film) is superior to the use of a noncrystalline silicon film (hereinafter referred to as an amorphous silicon film or a-Si film) as an active layer of thin film transistors (TFTs) acting as driver elements therein. This is because the mobility of the carriers of a polysilicon film (electron for n channel, positive hole for p channel, respectively) is higher than that of an amorphous silicon film, which makes it possible to minimize the pixel size (also called the cell size) and to realize a superfine structure. Moreover, a polysilicon TFT normally uses a quartz substrate and requires a high-temperature process that is carried out at 1000° C. or more. In contrast to this, with TFT formation technology using a low-temperature polysilicon film that requires only annealing of a silicon layer by irradiation of a laser beam, an inexpensive glass substrate can be used, because the substrate is not subjected to high temperatures, and high mobility TFTs can be formed thereon.

Since the mobility of the carriers becomes higher with an increase in the size of the polysilicon grains, techniques for forming polysilicon films having large grain sizes have been proposed. As disclosed in Patent Document 1, a method is generally adopted for this purpose in which pulsed laser light is shaped into a thin strip beam with its intensity distribution, in a minor axis direction (minor axis profile), formed into the shape of a trapezoid, and the light is irradiated onto a substrate in a pulsed manner while the light is being moved in the minor axis direction of the thin strip beam with a pitch of approximately 1/20 or so of the said minor axis width with every shot of the pulse. The a-Si film melts in response to an increase in temperature resulting from absorption of the laser beam irradiated thereon, and the melting causes the temperature to decrease. With such a temperature decrease, crystallization takes place in the a-Si film, and the a-Si film is transformed into a polysilicon film. The mean grain size of the polysilicon film changes depending on the energy density of the irradiation laser beam. For energy densities that are not less than the minimum energy density required for recrystallization of the a-Si film, the larger the energy density, the larger the grain size becomes. This threshold of the beam energy density on the low energy side is designated as “ELth.” However, when increasing the energy density to higher energy densities of a certain value or more, the polysilicon film becomes crystallites whose mean grain size is 100 nm (nanometer) or less. This threshold of the beam energy density on the higher energy side is designated as “EHth.” In order to attain suitable crystallization, the laser light must be irradiated with an energy density between “ELth” and “EHth.”

As an annealing laser for transforming the a-Si film into a polysilicon film, an XeCl excimer laser of 308 nm wavelength is commonly used. The reason for this is that this laser wavelength realizes a high annealing efficiency because the absorption maximum wavelengths of the a-Si film and of the polysilicon film both reside in the vicinity of 300 nm. Currently, among pulsed XeCl lasers that are used in commercialized laser annealers, a laser from Lambda Physik AG delivers the highest power, which reaches 300 W. Its pulse energy is 1000-1030 mJ, and the pulse repetition frequency is 300 Hz.

FIG. 13 is a diagram illustrating a laser annealing method. As shown in FIG. 13, in order to crystallize the whole surface of an a-Si film that has been formed on a large-sized glass substrate with dimensions of, for example, x=920 mm and y=730 mm, laser light 13 is shaped by an optical system to form a thin strip beam having a major axis L (mm) and a minor axis W (mm), and the beam thus shaped is irradiated onto the glass substrate 501 while the glass substrate 501 is being scanned in the minor axis direction of the beam. The pulse frequency f of the laser beam is set to, for example, 300 Hz (i.e., 300 shots/s). In order to enlarge the crystal grain size, it is necessary to irradiate a pulsed laser beam having an energy density required for the crystallization of the a-Si film onto the same position for a specified number of shots. Therefore, when designating the necessary number of pulse irradiations as S times, the distance P (P=V/f mm /shot) of movement between scanning pitches, i.e., pulses, is restricted to 1/S times the minor axis width W. Accordingly, the throughput of a process step of laser crystallization is proportional to both the minor axis width W and the pulse repetition frequency f, and it is inversely proportional to the number of shots S.

[Patent Document 1] JP-A No. 76715/1989

FIG. 14 is a diagram illustrating the configuration of a conventional excimer laser annealer. The reference numeral 100 denotes an optical-system housing including a laser light source 12, and the numeral 50 denotes a substrate accommodation housing. Laser light emitted from the optical-system housing 100 enters the substrate accommodation housing 50 via an irradiation lens 2 through a quartz window 51 of the substrate accommodation housing 50. A stage 14, on which a substrate 1 is supported, is accommodated inside the substrate accommodation housing 50. The stage 14 can be driven in two directions (x-direction and y-direction in FIG. 13), as well as in a rotational direction in the x-y plane (θ direction) and a perpendicular direction (z-direction) relative to the x-y plane, if necessary. An a-Si film is formed on the substrate 1. Hereafter, the substrate including this film simply will be called a substrate 1.

In the excimer laser annealer, the laser light is shaped into a long, thin strip beam. As shown in FIG. 14, the laser light 13 that is emitted from the excimer laser 12 passes though an attenuator 11, and it then enters a collimating optical system 10. In order to convert the laser light 13 into a uniform thin strip beam on the substrate 1, cylindrical array lenses are used as a homogenizer optical system. This homogenizer system includes an optical system 9 for the major axis direction and an optical system consisting of elements 6, 7, and 8 for the minor axis direction, which optical systems are installed separately. The laser light is shaped into a thin strip beam at a primary image plane 4, and it is irradiated onto the substrate 1 through a mirror 3, while its dimension is reduced only in the minor axis direction by the cylindrical lens 2.

FIG. 3A is a view showing the homogenizer optical system for the minor axis direction (called a minor axis homogenizer, for short) relative to the primary image plane 4 in FIG. 14. The minor axis homogenizer is constructed of a pair of optical elements, including a cylindrical lens array 7 (second stage), a cylindrical lens array 8 (first stage) and a collector lens 6 that are arranged along the optical axis of the laser beam. The collector lens 6 plays a role of combining the intensity profiles of array lenses of the lens array 8 on the primary image plane 4 to make the overall intensity distribution uniform. A lens 5, called a field lens, is used for adjusting the beam width in the primary image plane 4. The irradiation of the laser beam onto the substrate 1 (FIG. 14) is effected by transmitting the laser beam through a reduction optical system that images the intensity profile of the primary image plane 4 on the substrate 1 (reduction only in the minor axis direction). The dimensions of the thin strip laser light beam on the substrate 1 are 360 mm or more in the direction of the major axis length L and 0.4 mm in the direction of the minor axis width W. Here, a problem that exists in the minor axis distribution will be explained below.

Since the laser light 13 is irradiated onto the lens boundaries of the cylindrical lens array 8 in FIG. 3A, diffracted light is generated at these boundaries. A part of this diffracted light concentrates at both ends of the distribution on the primary image plane 4 after passing through corresponding lens elements of the other lens array. Originally, the distribution on the primary image plane 4 should be a uniform distribution, but both sides of the distribution, at which light rays of this diffracted light concentrate, become enhanced.

FIG. 2A is a diagram, showing the light intensity distribution in the optical system of FIG. 3A, with the horizontal axis representing a position in the x-direction in FIG. 13. Since sharp distribution portions at both ends of the light intensity distribution shown in FIG. 2A represent forms resembling dog ears, these portions will be referred to as dog-ear distributions for the sake of convenience. If the light intensity of this dog ear distribution is not less than the crystallite threshold EHth, crystallites will have grown in the polysilicon film obtained after the laser annealing, becoming the cause of a defective TFT device. Therefore, the energy density is set to satisfy a formula: EHth>E>ELth. The dog ear distribution has a detrimental effect in that it tends to narrow the process margin represented as [EHth−ELth] by ΔEdg. If ΔEdg>EHth−ELth, the process margin will be lost. Then, in order to remove or reduce these dog-ear distributions, conventionally, a method of projecting a distribution to a position spaced away from the primary image has been adopted plane to blur the intensity distribution.

FIG. 2B is a diagram showing the intensity distribution when a distribution at a position spaced away from the primary image plane is projected onto the substrate. In this case, the distribution takes on a trapezoidal shape. This case corresponds to a case where the primary image plane of FIG. 3A is shifted to the upstream side or the downstream side along the optical axis. In this case, the diffracted light does not form one sharp peak in each skirt distribution region because the diffracted light rays disperse to the skirt distribution regions at both sides of the trapezoid. However, this technique narrows the effective minor axis width. That is, almost the whole portion of the light existing in the skirt distributions of the trapezoid fails to satisfy the necessary energy density; thus, the skirt distributions are useless regions in terms of the laser energy. In an actual case, the value of “B” in FIG. 2B is approximately 0.4 mm, whereas the skirt part at each side exists with a width of approximately of 0.1 mm. In other words, the amount of energy loss reaches a high of 25% or so when calculating it with a formula: [area of skits of trapezoid]/[area of trapezoid]. This energy loss is one of the problems to be solved by the present invention.

### SUMMARY OF THE INVENTION

It is an object of the present invention to solve the above-mentioned problems. A further object of the present invention is to improve the throughput of the laser crystallization by up to 25% by enlarging the minor axis width of the laser light efficiently, thereby reducing the above-mentioned energy loss to near zero, so that the minor axis width is widened by up to 25%.

In order to solve the above-mentioned problem, the present invention interposes a filter for removing the dog ear in the light distribution characteristic of the optical system. FIG. 3B is a view showing one example of an optical system, from the homogenizer optical system for the minor axis direction according to this invention to the primary image plane 4, inclusive. As shown in FIG. 3B, a dog-ear removing filter 15, having a periodic mask structure, is disposed just before the lens array 7 of the minor axis homogenizer. Thereby, diffracted light 18, that is shown in FIG. 3A and results in the dog-ear distributions, can be removed. That is, since any beams, except for the diffracted light, converge on respective lenses of the second lens array, all that is necessary in order to remove the dog-ear profiles is just to remove all light except for these convergent beams.

FIG. 4 is a plan view showing the dog-ear removing filter that is used for the present invention. The structure of this dog-ear removing filter 15 consists of stripe-like mask areas 20 and non-mask areas 22. The mask area 20 is an area in which the transmittance of light is lowered, ideally providing zero transmittance. The non-mask area 22 is an area in which the transmittance of light is high, ideally providing 100% transmittance.

FIG. 2C is a diagram showing the intensity distribution with use of the dog-ear removing filter of the present invention. With use of this dog-ear removing filter 15, only the dog ears are removed, as shown in FIG. 2C, thereby realizing a preferable intensity distribution without losing a large amount of energy.

FIG. 1 is a diagram showing one example of the configuration of a laser annealer for manufacturing a polycrystalline semiconductor film in accordance with the present invention. Each of the same reference numerals as those used to identify elements in FIG. 14 corresponds to a similar component with the same function in FIG. 1. In FIG. 1, nine lens elements are provided in the lens array 7 of the minor axis homogenizer and in the lens array 8, but they are represented in the drawing by three lens elements for simplicity, respectively. Similarly, in FIGS. 3A, 3B, and 3C, each of these lens arrays is constituted by five lens elements. The dog-ear removing filter 15 must have a mask pattern corresponding to the number of the lenses in the lens arrays 7 and 8.

FIG. 3C is a diagram showing another example of the optical system, from the homogenizer optical system for the minor axis direction in accordance with this invention to the primary image plane 4, inclusive. In this configuration, two filters 15A, 15B for dog ear removal are arranged so as to sandwich the lens array 7. This configuration is used for increasing the removal efficiency of the diffracted light, that is, the dog-ear removing filter is modified to provide two sheets of filters in order to remove the diffracted light that cannot be removed completely using only a single filter.

As another method for avoiding the dog-ear distribution effect, the following method is conceivable. That is, it is possible to reduce only one dog-ear distribution portion, directing attention to the fact that only one dog-ear distribution portion of the dog-ear distributions on both sides has a detrimental effect on the crystallization. As shown in FIG. 13, the scanning direction of the laser beam is the minor axis direction of the thin strip beam; so that, even if the minor axis distribution has a dog-ear distribution portion at its head, a crystal that suffered the detrimental effect is recovered by annealing produced by the middle area of the distribution. Therefore, the existence of the first dog-ear portion in the minor axis distribution does not result in a permanent detrimental effect in the crystal. In contrast to this, the second dog-ear distribution portion having an energy EHth or more of the two dog-ear distributions in the minor axis distribution transforms the crystal into crystallites and goes away, while the area thus transformed remains as it is, which results in a bad crystal state. Here, the term “second” is used to refer to the dog-ear distribution by which the polysilicon film is irradiated secondly. Therefore, in order to circumvent the effect produced by the dog-ear distributions, it is only necessary to reduce the second dog-ear distribution to EHth or less.

FIGS. 5 and 7 show the optical system which is used to accomplish this objective. FIG. 5 is a view showing another example of the configuration of a laser annealer used for manufacturing a polycrystalline semiconductor film according to this invention. Each of the same reference numerals as those used to identify elements shown in FIG. 1 is used to identify a similar component with the same function in FIG. 5. Moreover, FIG. 7 is a view showing another example of the optical system, from the homogenizer optical system for the minor axis direction according to this invention as shown in FIG. 5 to the primary image plane 4, inclusive. In this configuration, a filter 23 for reducing the dog ear effect asymmetrically, which filter provides a stepped transmittance distribution, is disposed close to the primary image plane, with the low transmittance area corresponding only to the second dog-ear region, so that the height of that second do-ear distribution is made sufficiently low.

FIG. 8 is a plan view showing the filter 23 for reducing the dog ear effect asymmetrically, as used in the optical system shown in FIG. 5 and FIG. 7. The structure of this filter is such that two areas 24, 25, each having a different transmittance, are formed in the minor axis direction. FIGS. 6A to 6C are diagrams illustrating a distribution obtained with a filter capable of reducing the dog ear effect asymmetrically. FIG. 6A is a distribution in which dog ears have developed on the both sides of the characteristic. FIG. 6B is a transmittance distribution in the minor axis direction of the filter 23 shown in FIG. 7. The transmittance step ΔT1 in FIG. 6B corresponds to a transmittance difference between the area 24 and the area 25. The distribution shown in FIG. 6C is a finally obtained distribution. In this distribution, E is E<EHth, and ΔD is set as ΔD>0 in order to eliminate the detrimental effect of the second dog-ear distribution. In order to satisfy this condition, the transmittance step ΔT1 of the filter is set close to the second dog-ear distribution.

This invention relates to a way of reducing the energy loss of the intensity distribution in the scanning direction of the laser beam by use of an apparatus that realizes this objective in the crystallization process performed by laser annealing. By this apparatus, the minor axis width is expanded, and, thereby, the throughput is improved.

### BRIEF DESCRIPTION OF THE DRAWINGS

FIG. 1 is a diagram showing one example of the configuration of a laser annealer for use in manufacturing a polycrystalline semiconductor film according to this invention;

FIG. 2A is a characteristic diagram showing a light intensity distribution obtained in the optical system of FIG. 3A;

FIG. 2B is a characteristic diagram showing an intensity distribution in the case where the intensity distribution at a position spaced away from a primary image plane is projected onto a substrate;

FIG. 2C is a characteristic diagram showing an intensity distribution when a dog-ear removing filter in accordance with this invention is used;

FIG. 3A is a diagram showing an optical system, from a homogenizer optical system for the minor axis direction to the primary image plane;

FIG. 3B is a diagram showing one example of the optical system, from the homogenizer optical system for the minor axis direction according to this invention to the primary image plane;

FIG. 3C is a diagram showing another example of the optical system, from the homogenizer optical system for the minor axis direction according to this invention to the primary image plane;

FIG. 4 is a plan view showing a dog-ear removing filter of the type used for the present invention;

FIG. 5 is a diagram showing another example of the configuration of a laser annealer for use in manufacturing a polycrystalline semiconductor film according to this invention;

FIGS. 6A to 6C are diagrams showing a distribution obtained with a filter for reducing the dog ear effect asymmetrically;

FIG. 7 is a diagram showing another example of the optical system, from the homogenizer optical system for the minor axis direction according to this invention to the primary image plane shown in FIG. 5;

FIG. 8 is a plan view showing the filter for reducing the dog ear effect asymmetrically, as used in the system of FIG. 5 and FIG. 7;

FIG. 9 is a diagram illustrating a method of combining the minor-axis-distribution adjusting filter and the filter for reducing the dog ear effect asymmetrically at the primary image plane;

FIG. 10A is a characteristic diagram showing the light intensity distribution of the optical system of the second embodiment, before entering filters 23 and 26;

FIG. 10B is a diagram illustrating a filter having a stepped transmittance;

FIG. 10C is a characteristic diagram showing the light intensity distribution with an intensity step of the optical system of the second embodiment after passing through the filters 23 and 26;

FIG. 11A is a diagram showing another example of the optical system, from the homogenizer optical system for the minor axis direction according to this invention to the primary image plane 4, inclusive;

FIG. 11B is a diagram showing a method of combining two dog-ear removing filters in the case where two dog-ear removing filters are used;

FIG. 12A is a characteristic diagram showing the light intensity distribution of the optical system of FIG. 11A, before entering a filter 26;

FIG. 12B is a diagram showing a filter having a stepped transmittance;

FIG. 12C is a characteristic diagram showing the light intensity distribution with an intensity step of the optical system of FIG. 11A, after passing through the filter 26;

FIG. 13 is an illustration explaining a laser annealing method;

FIG. 14 is a diagram illustrating the configuration of a conventional excimer laser annealer; and

FIG. 15 is a diagrammatic sectional view the principal-part of an active-matrix type liquid crystal display device including a thin film transistor using the polysilicon thin film formed by a method of manufacture of this invention.

### DETAILED DESCRIPTION OF THE PREFERRED EMBODIMENTS

The preferred embodiments of this invention will be described below.

First Embodiment

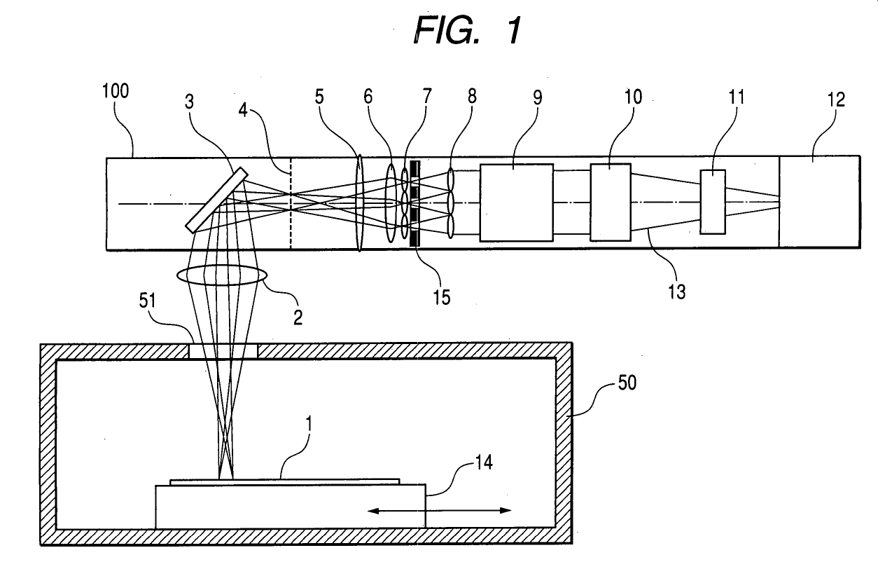

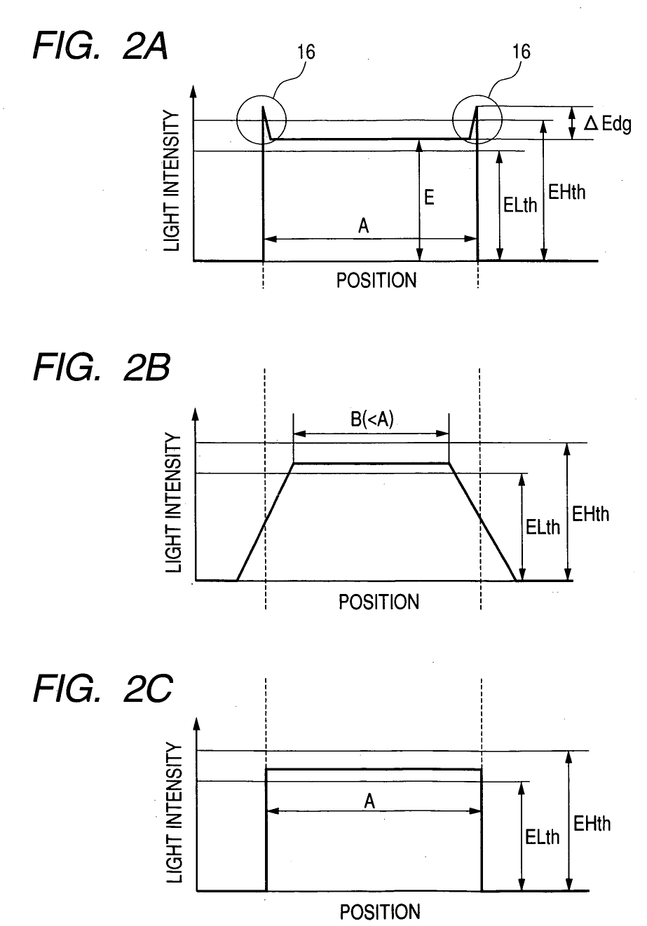

First, an embodiment in which the present invention is applied to an ordinary excimer laser annealer will be described. Its configuration is shown in FIG. 1. The laser 12 is a STEEL 1000 XeCl excimer laser, a product of Lambda Physik AG, with specifications: a wavelength of 308 nm (nanometer), a pulse duration width of approximately 27 ns (nanosecond), a pulse repetition frequency of 300 Hz (Hertz), and pulse energy of 1 J/pulse. The laser annealer is a product of Japan Steel Works, LTD., and it has a configuration in which a light beam is shaped into a thin strip beam having a major axis width of 365 mm and a minor axis width of 0.42 mm. The beam is irradiated onto a substrate disposed on a movable stage 14 through a quartz window 51 by the use of a major axis homogenizer optical system 9 obtained from MicroLas Lasersystem GmbH, a minor axis homogenizer optical system consisting of a pair of cylindrical array lenses 7, 8 and a collector lens 6, a field lens 5, a mirror 3x, and an irradiation cylindrical lens 2. The dog-ear removing filter 15 is disposed close to the beam convergence position of the minor axis homogenizer.

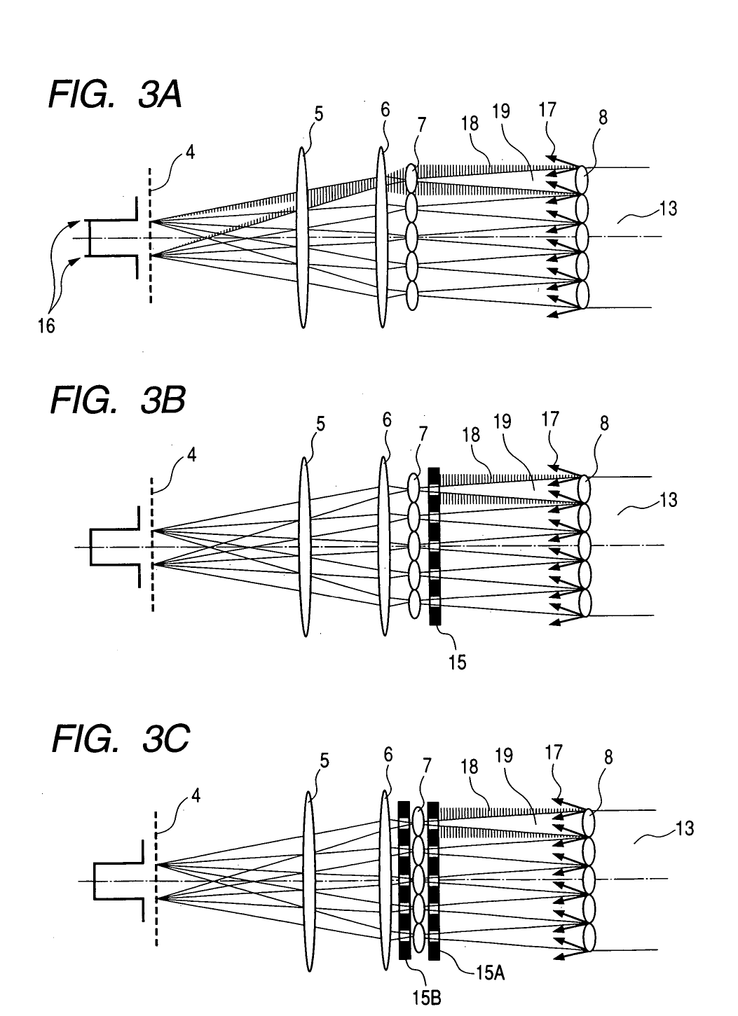

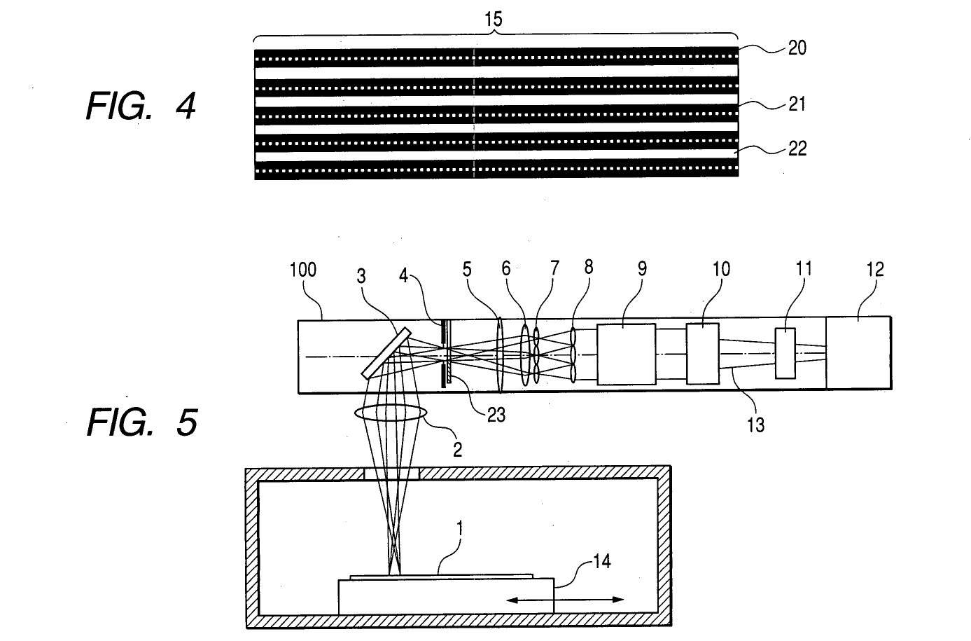

As has already been stated, the actual number of lens array elements is nine; however, it is seen in FIG. 3B, in an enlarged view of a location where the dog-ear removing filter 15 is disposed, as having a reduced number of five elements for simplicity. The dog-ear removing filter 15 is depicted as having three lens array elements in FIG. 1. The dog-ear removing filter 15 has a structure such that stripe-like mask areas 20 and non-mask areas 22 are formed on a quartz substrate, as shown in FIG. 4. The mask area 20 is formed with a high reflectance coating having a transmittance of 80% or less, 2 and the non-mask area 22 is formed with an antireflection coating having a transmittance of 99% or more. The dog-ear removing filter 15 is disposed so that boundaries 21 of the array lens elements 7 coincide with the centers of the mask areas. The mask area 20 can also be formed by micro blasting, instead of using the high reflectance coating. In this case, since reduction of transmittance is produced by scattering caused by surface roughness, it is possible to adjust the transmittance to 80% or less by adjusting the degree of surface roughness.

Metals, such as aluminum (Al), can also be used for the mask area. As shown in FIG. 3C, two dog-ear removing filters 15A, 15B that sandwich the second-stage minor axis homogenizer 7 can be used instead of the dog-ear removing filter 15, and this configuration can increase the efficiency of removal of diffracted light. For an optical system in which the beam convergence position is shifted from the second-stage minor axis homogenizer 7, the configuration where the single dog-ear removing filter 15 is disposed in the beam convergence position is recommended. In the case of an optical system in which the beam convergence position coincides with the second-stage minor axis homogenizer 7, it is impossible to dispose the filter 15 in the beam convergence position; therefore, the adoption of the two filter configuration improves the dog-ear removal efficiency.

By use of the above-described arrangement, it has become possible to enlarge the minor axis width by up to 25%, and, consequently, the minor axis width W can be set to a value in the range of 0.4 mm to 0.5 mm at the maximum.

A method of combining this embodiment with a technique for increasing the process margin pertinent to the energy density of crystallization will be described below. This method is a method where the intensity distribution in the minor axis direction is not flat, but is provided with a step in the intensity distribution. The inventors of this invention have verified that the process margin can be widened by setting this step to 5-8% of the intensity.

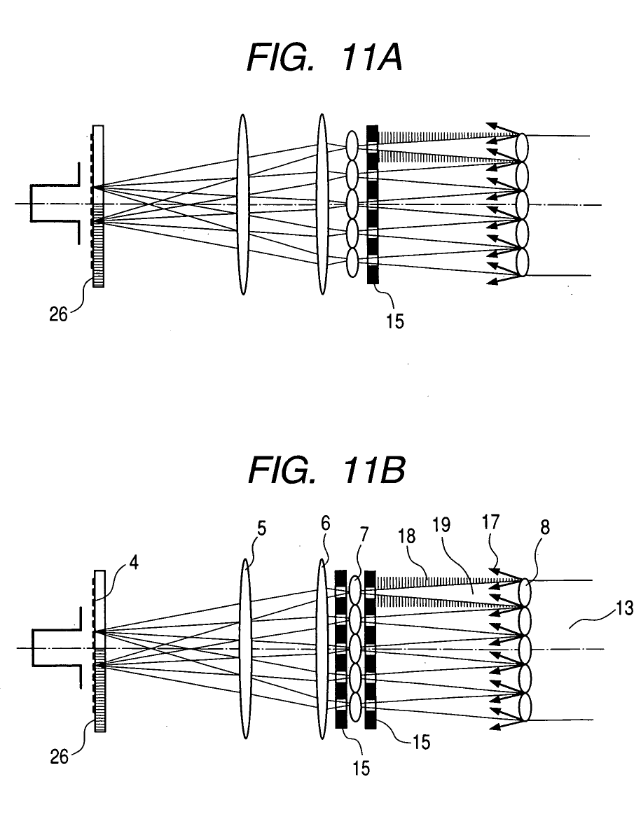

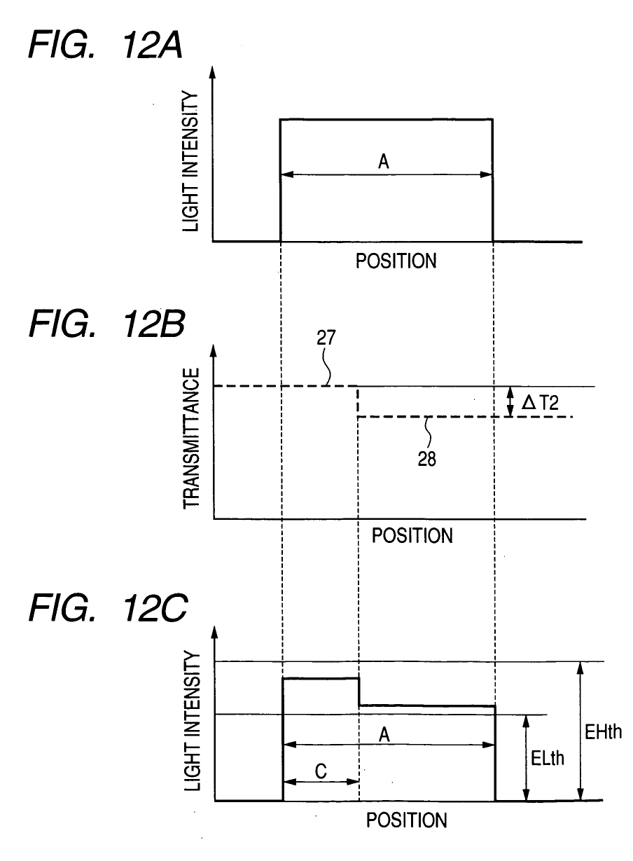

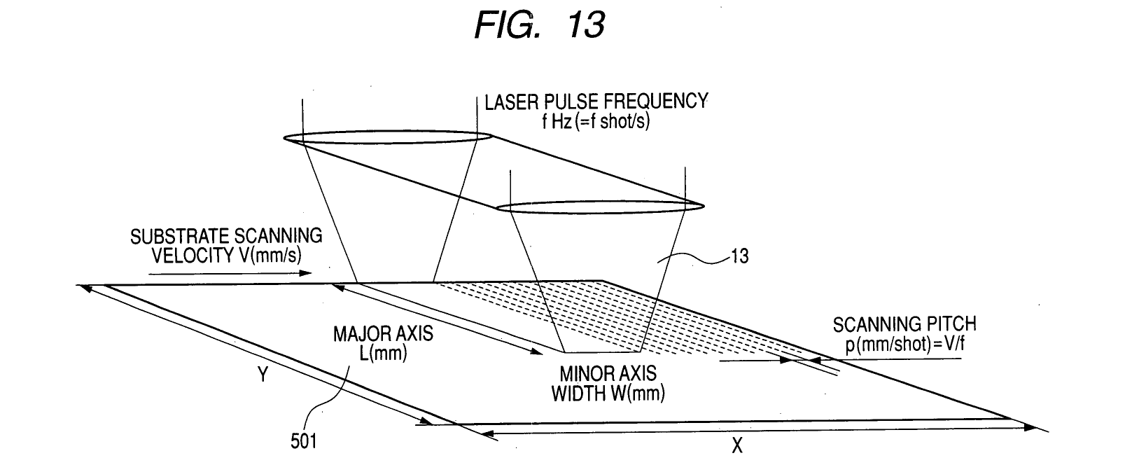

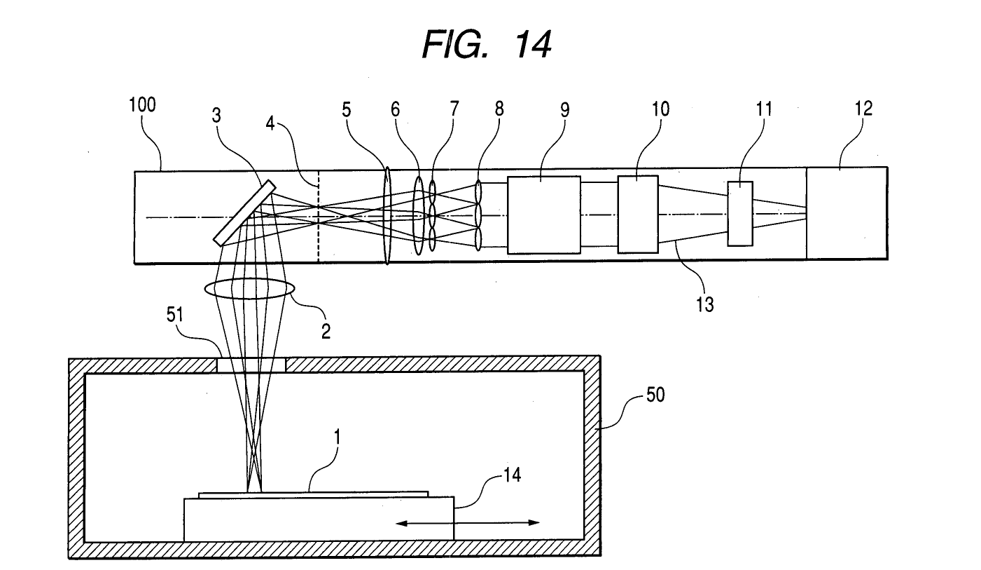

FIG. 11A is a diagram showing another example of the optical system, from the homogenizer optical system for the minor axis direction according to this invention to the primary image plane 4, inclusive. FIGS. 12A to 12C show the light intensity distribution in the optical system in FIG. 11A. In the configuration shown in FIG. 11A, a minor-axis-distribution adjusting filter 26 for adjusting the minor axis distribution is disposed at the primary image plane. By this arrangement, the initial profile is converted to a stepped profile, as shown in FIGS. 12A, 12B, and 12C. This minor-axis-distribution adjusting filter 26 is formed with coatings in such a way that the transmittance of a coating in the area 27 that allows the laser beam to be transmitted and irradiated onto the substrate firstly differs from the transmittance of a coating in the area 28 that allows the laser beam to be transmitted and irradiated onto the substrate subsequently by 5-8%, and, more specifically, the transmittance of the area 27 should be 98%, whereas the transmittance of the area 28 should be in the range 93-90%. It is preferable that the step position in the transmittance of the minor-axis-distribution adjusting filter 26 in the minor axis direction is set to a C/A value falling within a range from ¼ to ¾, as seen in FIG. 12C. FIG. 11B shows a method of combining the filter 26 and the two dog-ear removing filters 15 when using two filters.

Next, a method used for annealing the substrate 1, which is fabricated as a sample using the configuration of FIG. 1, will be explained. The substrate 1 of the sample is fabricated as follows: two kinds of buffer layers consisting of a silicon nitride film of approximately 50-nm thickness and a silicon oxide film of approximately 100-nm thickness are formed in a glass substrate with a short side length x of 730 mm and a long side length y of 920 mm; and an a-Si film of approximately 50 nm thickness is formed thereon, each layer being deposited by plasma CVD. A beam of laser light is shaped to a thin strip beam with a major axis L of 365 mm and a minor axis W of 0.42 mm or more. The thin strip beam is scanned in parallel to the long side L of the substrate 1, with its major axis being set to the short side of the substrate 1. This scanning direction coincides with the minor axis direction of the thin strip beam. The width of the intensity distribution in this minor axis direction can be adjusted by adjusting the positions of three kinds of optical elements 6, 7, and 8, constituting the minor axis homogenizer, and of the field lens 5.

Scanning of the substrate is carried out by placing the substrate on the movable stage 14. In order to control the mean grain size of the polysilicon film to be 300 nm or more, the irradiation energy density and the number of laser pulse shots on the same position are made identical to conditions used before applying this invention. That is, scanning is carried out under the following conditions: an irradiation energy density of 380 mJ/cm² or more, and 20 or more shots on the same position. When the minor axis width W is expanded from 0.4 mm to 0.5 mm at the maximum, which is a 25% increase relative to 0.4 mm, with those conditions satisfied, the distance of movement between laser pulses increases from 0.02 mm (a minor axis width of 0.4 mm/20-times) to 0.025 mm (a minor axis width of 0.5 mm/20-times), and the scanning velocity increases from 6 mm/s to 7.5 mm/s.

As a result, a time required to anneal the whole surface of the substrate having dimensions of 730 mm×920 mm becomes 4.9 min/substrate at the minimum, which results from enlargement of the minor axis width according to this embodiment, which is shorter than 6.5 min/substrate in the case of no use of this embodiment, thereby improving the throughput. Although the value of the throughput depends on the substrate size and laser specifications (the maximum pulse energy and the pulse repetition frequency), the throughput is improved by up to 25%. The description given above is for the configuration of FIG. 1 that uses a single dog-ear removing filter 15. The same annealing method can be applied to an apparatus using two dog-ear removing filters 15, as well as to an apparatus using a combination of the two dog-ear removing filters 15 and the filter 26.

Next, the production capacity of a production line and an effect of this embodiment thereon will be described. The maximum production capacity of a thin film transistor (TFT) production line using the polysilicon film crystallized by laser annealing cannot exceed a value specified by the number of laser annealers installed in the line. According to this embodiment, since the manufacturing capacity per annealer is improved by 25%, the production capacity of the line can be improved by up to 25%. In order to evaluate the production capacity, it is also necessary to consider the manufacturing yield. The manufacturing yield can be calculated by finding the number of non-defective substrates obtained by multiplying the number of chips to be shipped with an area of one chip and dividing this number by the number of glass substrates inputted into the production line. The maximum production capacity is calculated based on the production capacity in a certain period using the total number of procured glass substrates in that period, as well as the manufacturing yield and the number of chips per substrate. In this embodiment, the manufacturing capability can be increased by up to 25% without increasing the number of installed laser annealers. The polysilicon film manufactured in accordance with the above-mentioned first embodiment has a scanning pitch of 0.02 mm to 0.025 mm. A scanning pitch of at least 0.021 mm or more becomes possible.

Second Embodiment

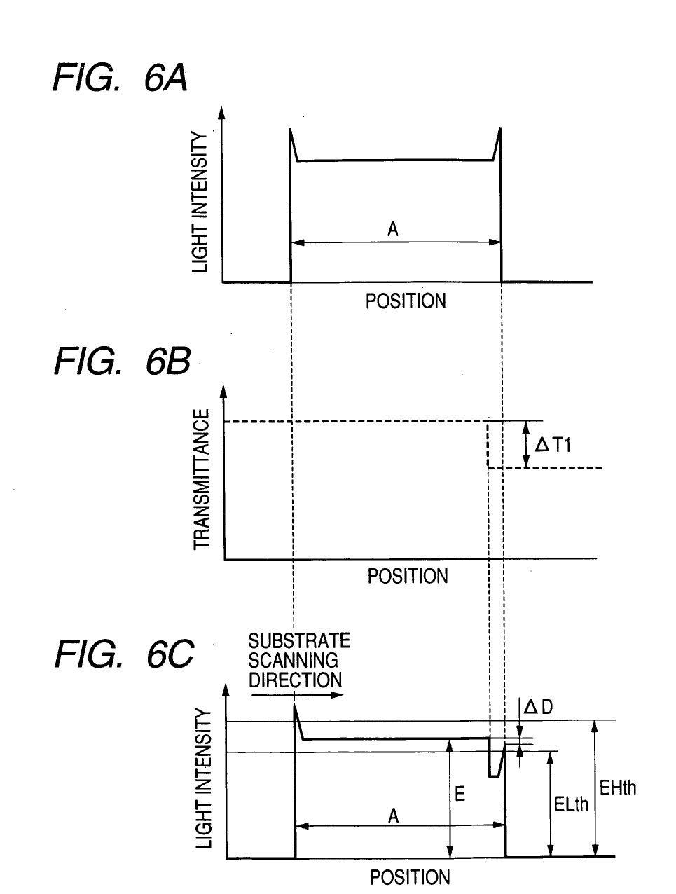

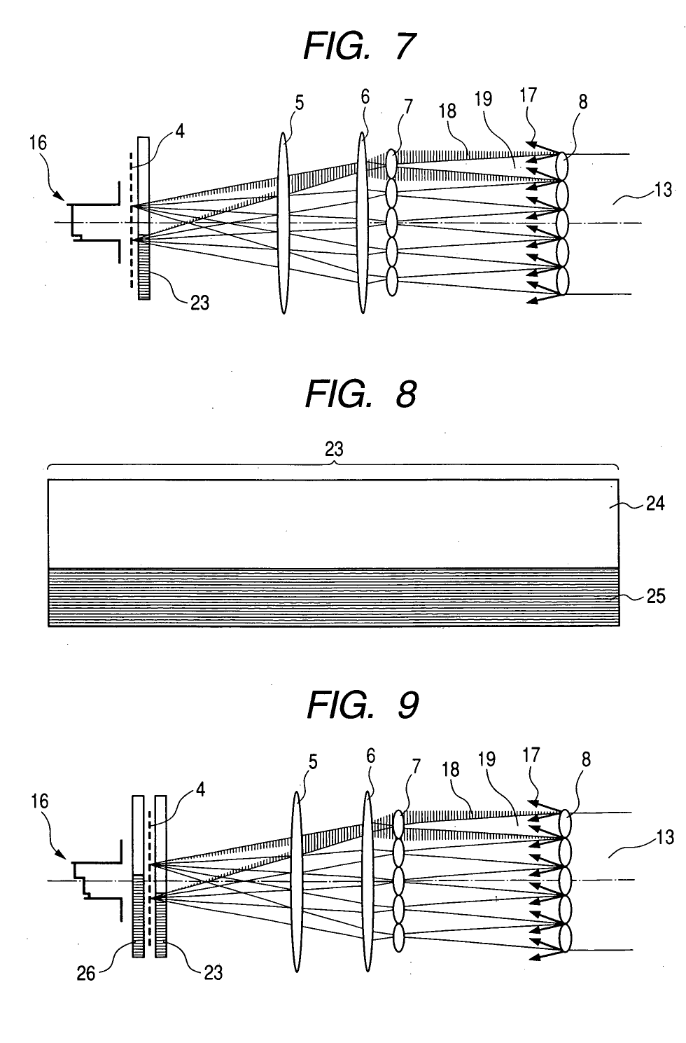

Next, a second embodiment of the present invention will be explained with reference to FIG. 5, FIG. 6, and FIG. 7. The basic configuration of a laser annealer, including a laser, is the same as that of the first embodiment. In the second embodiment, instead of the dog-ear removing filter 15, a filter 23 for reducing the dog ear effect asymmetrically is disposed at the primary image plane 4, as shown in FIG. 5. This filter is formed of a quartz substrate on which coating areas, each having a different transmittance, are formed so that two kinds of areas 24, 25 are arranged in the minor axis direction, as shown in FIG. 8. The area 24 is provided with reflection reducing coatings having a residual reflection of 1% on the front and back sides, achieving 98% transmittance. On the other hand, the transmittance of the area 25 is set to a value in the range of 97-0%.

In this case, the value of ΔT1 in FIG. 6B is allowed to be in the range of 1-98%. A most suitable value of ΔT1 is a value such that the height of the second dog-ear distribution is not more than EHth, as shown in FIG. 6C, and the energy loss is lowest, that is, a case where ΔD=0 is satisfied. The filter 23 for reducing the dog ear effect asymmetrically, whose transmittance was set to 98% in the area 24 and 88% in the area 25, as practical values, was manufactured, and ΔD was made almost zero with a setting of ΔT1=10%.

The above-stated setting enables the minor axis width W to be enlarged by up to 25%. That is, it became possible to expand the minor axis width W to up to 0.5 mm from 0.4 mm.

A method of combining this second embodiment and a technique for expanding the process margin pertinent to the energy density of crystallization will be described below. This method does not use a flat intensity distribution, but employs a stepped intensity distribution in the minor axis distribution. The inventors of this invention have verified that, when this intensity step is set to any value in the range of 5-8%, the process margin is widened.

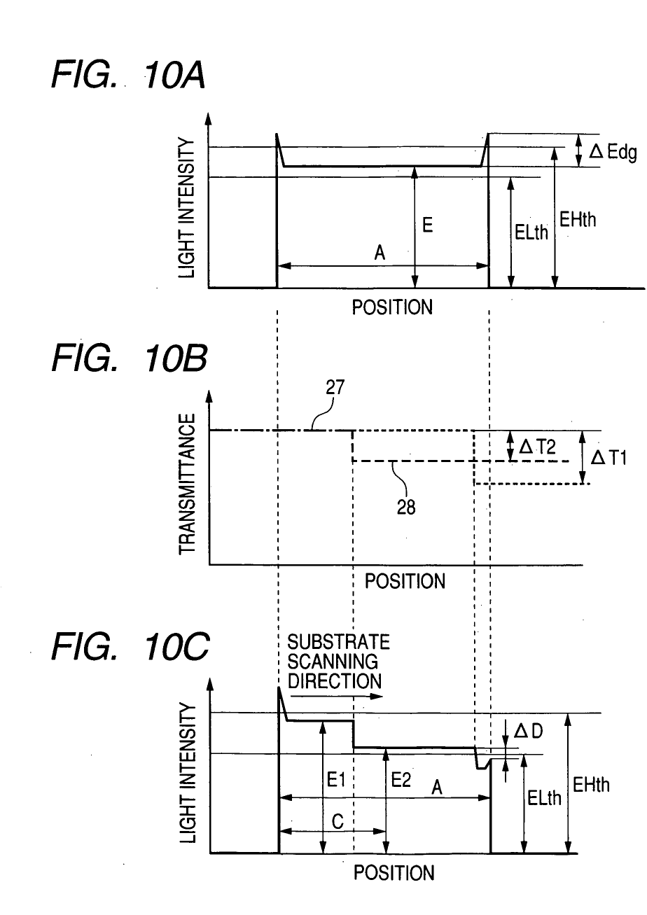

FIG. 9 is a view showing how the minor-axis-distribution adjusting filter 26 and the filter 23 for reducing the dog ear effect asymmetrically are combined at the primary image plane. FIG. 10 is a diagram illustrating the light intensity distribution in the second embodiment. As shown in FIG. 9, by disposing the minor-axis-distribution adjusting filter 26 on which a stepped transmittance is formed at the primary image plane, the light intensity distribution is converted into a stepped profile, as shown in FIG. 10C. The minor-axis-distribution adjusting filter 26 is formed with coatings in such a way that the transmittance of a coating in an area 27 that allows the light beam to be transmitted and irradiated onto the substrate firstly differs from the transmittance of a coating of an area 28 that allows the light beam to be transmitted and irradiated onto the substrate subsequently by 5-8%, and, more specifically, the transmittance of the area 27 should be 98%, whereas the transmittance of the area 28 should be in the range of 93-90%. Preferably, the position of the transmittance step in the minor-axis-distribution adjusting filter 26 is set in a range where the C/A value in FIG. 10C is ¼ to ¾.

The method of annealing the sample substrate 1 in this second embodiment is the same as in the first embodiment. Note that the light beam must be scanned in such a way that a portion of the generated dog-ear distribution that is not diminished in the minor axis distribution direction is irradiated on the substrate 1 prior to a portion of the reduced dog-ear distribution, as shown in FIG. 6C and FIG. 10C. This second embodiment, as with the first embodiment, makes it possible to increase the production capacity by up to 25% without increasing the number of elements of the installed laser annealer.

In the polysilicon film formed in this embodiment, the scanning pitch can be set to a value in a range from 0.02 mm to 0.025 mm. A scanning pitch of at least 0.021 mm or more becomes possible.

Third Embodiment

Next, a thin film transistor that is formed using the polycrystalline thin film prepared by each of the methods described above and an embodiment of a display device constructed with a drive circuit including this thin film transistor and a pixel circuit will be described.

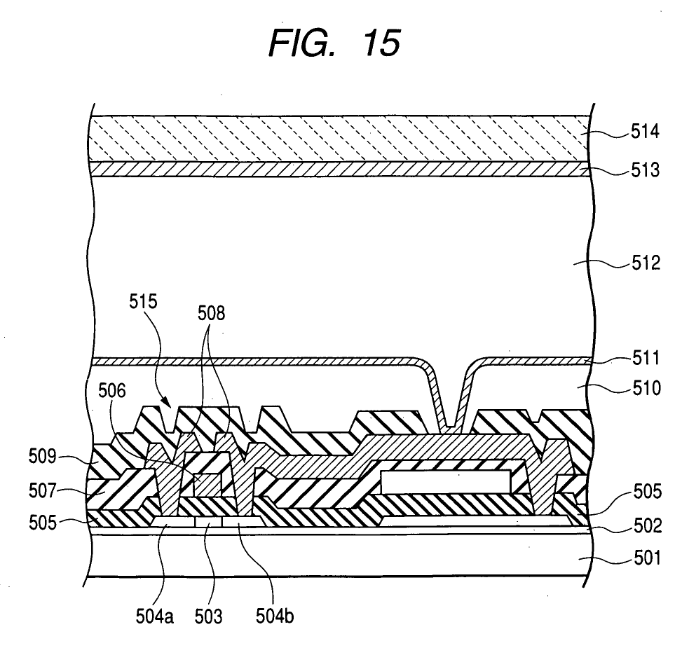

FIG. 15 is a sectional view showing an example of a principal-part of an active-matrix type liquid crystal display device that comprises a thin film transistor using a polysilicon thin film prepared in accordance with this invention and which operates as a display device. This liquid crystal display device is constructed as follows. That is, liquid crystal 512 is placed in a space between a glass substrate 501, which is equipped with a thin film transistor (TFT) 515, a color filter 510 and a pixel electrode 511, and an opposite glass substrate 514 having a counter electrode 513, which space is enclosed. Note that an orientation control film is formed at a boundary between the liquid crystal 512 and the substrate, but its illustration is omitted.

On the principal surface of the glass substrate 501, an undercoat layer 502 (consisting of a silicon oxide film and a silicon nitride film) is formed, and an amorphous silicon semiconductor layer is formed thereon. This amorphous silicon semiconductor layer is modified to form a layer of the polysilicon thin film (polysilicon film) by laser annealing according to this invention, as was explained in conjunction with the foregoing embodiments. A thin film transistor 515 is built in the layer of the polysilicon thin film obtained by this annealing. That is, a source semiconductor layer 504a of polysilicon and a drain layer 504b of polysilicon are formed by doping impurities into both sides of the semiconductor layer 503, which is made up of a polysilicon semiconductor thin film, and a gate electrode 506 is formed thereon along with an intermediate gate oxide film (gate insulating layer) 505.

Source/drain electrodes 508 are connected to the source semiconductor layer 504a and the drain semiconductor layer 504b through contact holes formed in an interlayer insulating film 507, respectively, and an overcoat 509 is formed thereon. The color filter 510 and the pixel electrode 511 are formed on the overcoat 509. In the laser annealing of the first embodiment and the second embodiment of this invention, the scanning pitch can be set in a range from 0.02 mm (not inclusive) to 0.025 mm (maximum). This period appears as periodic changes, such as the sheet resistance of the polysilicon substrate and the mobility. In the operating characteristics of a display panel, a period of display nonuniformity when operating with a voltage lower than an operating threshold voltage is detected as the minimum multiple of the laser scanning pitch and the pixel pitch. Moreover, this period also remains in the period of the surface roughness of the polysilicon film.

This thin film transistor constitutes the pixel circuit of a liquid crystal display device, in which a pixel electrode 511 is selected by a selection signal from an unillustrated scanning-line drive circuit and is driven by an image signal supplied from an unillustrated signal-wire drive circuit. An electric field is formed between the pixel electrode 511 being driven and the counter electrode 513 that is provided on the inner surface of the opposite glass substrate 514. The electric field controls the orientation direction of molecules of the liquid crystal 512 to produce a display.

Note that it is also possible to form the thin film transistors constituting the above-mentioned scanning-line drive circuit and the signal-wire drive circuit using a polysilicon semiconductor thin film, as with the above-mentioned pixel circuit. Moreover, this invention is applicable not only to a liquid crystal display device, but also to other display devices of the active-matrix type, such as an organic EL display device, a plasma display device, and other various display devices. Furthermore, this invention is similarly applicable to the manufacture of a semiconductor thin film constituting a solar cell.

This invention makes it possible to manufacture a polysilicon semiconductor substrate at a high throughput that is used when forming a TFT on a glass substrate and making an image display panel and a solar cell therewith.

1-3. (canceled)

4. An apparatus for manufacturing a polycrystalline semiconductor film that irradiates pulsed laser light beam onto an amorphous semiconductor film while it is being scanned and transforms the amorphous semiconductor film into a polycrystalline state, the apparatus comprising:
an optical system that, using a laser light source delivering pulsed baser bight beam of energy of 1030 mJ or less, shapes the laser light beam into a thin strip beam whose major axis length is 350 mm or more and renders the intensity distribution of the irradiation baser beam uniform; and
a filter for eliminating diffracted light occurring in the optical system,
wherein the filter enlarges a scanning direction width of the light intensity distribution to exceed 0.42 mm.

5. The apparatus for manufacturing a polycrystalline semiconductor film according to claim 4, wherein
the optical system for rendering the light intensity distribution in the irradiation laser beam uniform has both a bens array and a filter for eliminating diffracted light occurring at boundaries between array lenses of the lens array.

6. The apparatus for manufacturing a polycrystalline semiconductor film according to claim 4, wherein
an optical system for rendering the light intensity distribution of the irradiation laser beam uniform is provided with a filter for eliminating diffracted light occurring in the optical system as a means for widening the scanning direction width of the light intensity distribution in the irradiation laser beam.

7. The apparatus for manufacturing a polycrystalline semiconductor film according to claim 4, wherein
the apparatus of manufacturing a polycrystalline semiconductor film has a lens array as a means for rendering the light intensity distribution in the irradiation laser beam uniform, and a filter for eliminating diffracted light occurring at boundaries between array lenses of the lens array is disposed.

8. An apparatus for manufacturing a polycrystalline semiconductor film that comprises laser light source equipment and a stage that carries an insulating substrate on whose surface an amorphous semiconductor film is formed thereon, the amorphous semiconductor film being transformed into a polycrystalline film by irradiating the laser light beam emitted from the baser light source equipment onto the insulating substrate while it is being scanned, wherein
the laser light source equipment comprises:
a laser light source; and
a major axis homogenizer optical system and a minor axis homogenizer optical system both for shaping the laser beam from the laser light source into a thin strip;
a minor axis homogenizer optical system having a first-stage cylindrical lens array and the second-stage cylindrical lens array both disposed along the optical axis of the baser light, and the minor axis homogenizer optical system being equipped with a filter that removes diffracted light occurring at boundaries of lens elements of the first-stage cylindrical lens.

9. The apparatus for manufacturing a polycrystalline semiconductor film according to claim 8, wherein
the filter is disposed just before the second-stage cylindrical lens array.

10. The apparatus for manufacturing a polycrystalline semiconductor film according to claim 8, wherein
the filters are disposed just before and immediately after the second-stage cylindrical lens array.

11. An apparatus for manufacturing a polycrystalline semiconductor film that comprises laser light source equipment and a stage that carries an insulating substrate on whose surface an amorphous semiconductor film is formed on it, the amorphous semiconductor film being transformed into a polycrystalline film by irradiating a baser light beam emitted from the laser light source equipment onto the insulating substrate while it is being scanned, wherein
the laser light source equipment comprises:
a laser light source;
a major axis homogenizer optical system for shaping the laser beam from the baser light source; and
a minor axis homogenizer optical system for shaping the baser beam from the laser bight source;
the minor axis homogenizer optical system comprising a first-stage cylindrical lens array and a second-stage cylindrical lens array both being disposed along the optical axis of the laser light, and
an asymmetry reducing filter that reduces a later-coming part of a laser light intensity in the scanning direction arising from diffracted light occurring at boundaries of lens elements of the first-stage cylindrical lens array being disposed just before a primary image plane of the minor axis homogenizer optical system being disposed.

12. The apparatus for manufacturing a polycrystalline semiconductor film according to claim 11, wherein
a minor-axis-distribution adjusting filter for adjusting a laser bight intensity distribution in the minor axis direction is disposed downstream the filter for reducing asymmetry at the primary image plane.

13. (canceled)
